(19) United States
(12) Patent Application Publication
(10) Pub. No.: US 2026/0290741 A1
(43) Pub. Date: Sep. 24, 2026

(54) METHOD, APPARATUS AND SYSTEM FOR CHARACTERIZING ENERGETIC NEUTRAL COMPONENT OF A PARTICLE BEAM

(71) Applicant: Axcelis Technologies, Inc., Beverly, MA (US)

(72) Inventor: Michael Cristoforo, Beverly, MA (US)

(73) Assignee: Axcelis Technologies, Inc., Beverly, MA (US)

(21) Appl. No.: 19/084,939

(22) Filed: Mar. 20, 2025

(51) Int. Cl. H01J 37/02; H01J 37/05; H01J 37/244; H01J 37/317

(52) U.S. Cl. CPC H01J 37/026; H01J 37/05; H01J 37/244; H01J 37/3171; H01J 2237/24535; H01J 2237/24564

(57) ABSTRACT

A method of determining an energetic neutral beam current component of a particle beam having both energetic ions and energetic neutrals includes receiving the particle beam at a particle beam detector; determining a first value corresponding to a first secondary electron current generated by both the energetic ions and the energetic neutrals, and determining a second value corresponding to a second secondary electron current generated by the energetic neutrals; and quantifying the neutral beam current component with respect to an energetic ion beam current of the particle beam using the determined first and second values.

### BACKGROUND

The present invention relates generally to semiconductor device manufacturing and, more specifically, to a method, apparatus and system for characterizing an energetic neutral component of a particle beam containing both energetic ions and neutrals.

In the manufacture of semiconductor devices and other related products, ion implantation systems are used to impart dopant elements, generated in an ion source and transported in an ion beam, into semiconductor wafers, display panels, or other types of workpieces. Typical ion implantation systems, or ion implanters, impact a workpiece with an ion beam utilizing a known process, or recipe, in order to produce n-type or p-type doped regions, or to modify layers in the workpiece to enhance or impart other beneficial properties, such as hydrogen ions to produce cleave planes. When used for precise doping of semiconductors, the ion implantation system injects selected ion species to produce a desired extrinsic material.

Among the primary control factors for ensuring precisely doped semiconductors in an ion implanter are the implant energy and implant dose. Implant energy is generally controlled through the use of accelerating or decelerating stages, solely or in combination, for example utilizing DC or RF power supplies operably coupled to lenses disposed within the evacuated beamline region of the implanter. The implant dose is a function of the actual delivered beam current over time, and where the precision of the dose depends upon an accurate beam current measurement.

Beam current measurement may be achieved, for example, by directing the ion beam into a Faraday assembly or similar detector. The Faraday assembly may, for example, comprise a target plate which receives the beam. Positively charged ions incident upon the target plate attract electrons therefrom, in turn causing a current to flow in a dosimetry circuit, the value of which is relayed to a controller. To ensure accurate readings, suppression electrodes may be provided such that any secondary electrons liberated from the detector surface from the impact of the incident ion beam to return to the detector, thereby ensuring an accurate reading of the ion beam current.

### SUMMARY

In one embodiment, a method of determining an energetic neutral beam current component of a particle beam having both energetic ions and energetic neutrals includes receiving the particle beam at a particle beam detector, wherein the particle beam comprises energetic ions and energetic neutrals, determining a first value corresponding to a first secondary electron current generated by both the energetic ions and the energetic neutrals, determining a second value corresponding to a second secondary electron current generated by the energetic neutrals, and quantifying the neutral beam current component with respect to an energetic ion beam current of the particle beam using the determined first and second values.

In a further embodiment, a method of characterizing a neutralization of a particle beam having both energetic ions and energetic neutrals includes receiving the particle beam at a target electrode of a particle beam detector; measuring, at the target electrode, a total target electrode current (T₁) that comprises a sum of an energetic ion beam current (I) and a first secondary electron current (C₁), the first secondary electron current (C₁) being generated at the target electrode by both the energetic ions and the energetic neutrals; receiving and measuring, at a collector electrode of the particle beam detector, the first secondary electron current (C₁) emitted from the target electrode. The method further comprises selectively diverting the energetic ions of the particle beam such that only the energetic neutrals are received at the target electrode, and measuring a second secondary electron current (T₂), the second secondary electron current (T₂) being generated at the target electrode only by the energetic neutrals; and determining an energetic neutral beam current component (N) of the particle beam using the total target electrode current (T₁), the first secondary electron current (C₁), and the second secondary electron current (T₂).

In a still further embodiment, a particle beam detector apparatus includes a target electrode configured to receive an incident particle beam, the incident particle beam having both energetic ions and energetic neutrals; a collector electrode configured to capture secondary electrons generated at the target electrode; and one or more deflection electrodes configured to selectively divert the energetic ions away from a beam axis that intersects the target electrode. In another embodiment, a particle beam current detection system includes a target electrode configured to receive an incident particle beam, the incident particle beam having both energetic ions and energetic neutrals; a collector electrode configured to capture secondary electrons generated at the target electrode; one or more deflection electrodes configured to selectively divert the energetic ions away from a beam axis toward the target electrode; a first current measuring device coupled to the target electrode; a second current measuring device coupled to the collector electrode; a first variable voltage supply coupled to the one or more deflection electrodes; and a second variable voltage supply coupled to the collector electrode. In another embodiment, an ion implantation system includes an ion source configured to form an ion beam; a mass analyzer configured to mass analyze the ion beam; a bending element positioned downstream of the mass analyzer and configured to bend a trajectory of the ion beam and a particle beam detector, wherein the particle beam detector further includes a target electrode configured to receive an incident particle beam having both energetic ions and energetic neutrals, a collector electrode configured to capture secondary electrons generated at the target electrode and one or more deflection electrodes configured to selectively divert the energetic ions away from a beam axis toward the target electrode. The particle beam detector further includes a first current measuring device coupled to the target electrode, a second current measuring device coupled to the collector electrode, a first variable voltage supply coupled to the one or more deflection electrodes, a second variable voltage supply coupled to the collector electrode and a controller configured to determine an implant current of the ion beam at the workpiece based, at least in part, on the calculated percentage of ion beam neutralization of the particle beam.

### BRIEF DESCRIPTION OF THE DRAWINGS

Aspects of the present disclosure are best understood from the following detailed description when read with the accompanying figures.

FIG. 1 is a flowchart illustrating a method of determining an energetic neutral beam current component of a particle beam having both energetic ions and energetic neutrals, in accordance with an exemplary embodiment.

FIG. 2(a) is a cutaway perspective view of an exemplary particle beam detector that may be used to implement the method illustrated in FIG. 1, in accordance with an exemplary embodiment.

FIG. 2(b) is a schematic representation of the particle beam detector illustrated in FIG. 2(a).

FIG. 3 is a schematic representation of an alternative embodiment of the particle beam detector illustrated in FIG. 2(b).

FIG. 4 is a perspective view of a portion of an ion implanter beamline module, having a particle beam current detection apparatus operably mounted therein, in accordance with an exemplary embodiment.

FIG. 5 is a graph that illustrates self-check data associated with a mode of operation of one embodiment of the invention.

FIG. 6 is a graph illustrating a percentage of neutrals (neutral fraction) versus beamline pressure in an ion implanter for a given pressure, introduced by an N₂ gas bleed.

### DETAILED DESCRIPTION

The present disclosure is directed generally toward various apparatuses, systems, and methods associated with implantation of ions into a workpiece. More specifically, the present disclosure is directed to characterizing an energetic neutral component of a particle beam containing both energetic ions and neutrals. The particle beam may, for example, be generated and transported in an ion implanter.

Accordingly, embodiments of the present invention will now be described with reference to the drawings, wherein like reference numerals may be used to refer to like elements throughout. It is to be understood that the description of these aspects is merely illustrative and that they should not be interpreted in a limiting sense. In the following description, for purposes of explanation, numerous specific details are set forth in order to provide a thorough understanding of the present invention. It will be evident to one skilled in the art, however, that the present invention may be practiced without these specific details. Further, the scope of the invention is not intended to be limited by the embodiments or examples described hereinafter with reference to the accompanying drawings but is intended to be only limited by the appended claims and equivalents thereof.

It is also noted that the drawings are provided to give an illustration of some aspects of embodiments of the present disclosure and therefore are to be regarded as schematic only. In particular, the elements shown in the drawings are not necessarily to scale with each other, and the placement of various elements in the drawings is chosen to provide a clear understanding of the respective embodiment and is not to be construed as necessarily being a representation of the actual relative locations of the various components in implementations according to an embodiment of the invention. Furthermore, the features of the various embodiments and examples described herein may be combined with each other unless specifically noted otherwise.

It is also to be understood that in the following description, any direct connection or coupling between functional blocks, devices, components, circuit elements or other physical or functional units shown in the drawings or described herein could also be implemented by an indirect connection or coupling. Furthermore, it is to be appreciated that functional blocks or units shown in the drawings may be implemented as separate features, circuits, or components in one embodiment, and may also or alternatively be fully or partially implemented in a common feature, circuit, or component in another embodiment. Further, several functional blocks, for example, may be implemented as software running on a common processor or controller.

As a practical matter, the operation of an ion implanter or other ion beam equipment (e.g., linear accelerators) may result in the production of energetic neutral particles which can be transported with the ion beam. That is, a particle beam may include energetic neutral particles (neutrals) in addition to energetic ions. These neutral particles may arise, for example, from charge exchange interactions between the ion beam and background gas molecules in the ion implanter, or from gases deliberately introduced during operation, such as in the ion source or in the plasma electron flood, or from outgassing from the workpiece being implanted. This latter effect is of particular concern if the workpiece is coated with a coating such as a photoresist material.

Energetic neutral particles arriving at the beam current measurement device will not be measured by a Faraday detector. Further, these neutral particles may still impart dose to the wafer, provided an ion separation mechanism is not present between the point of generation and the workpiece. Thus, a conventional dosimetry system may underestimate the effective beam current and result in the wafer being overdosed. Further complications may arise if the effective kinetic energy of the neutrals differs from that of the ions, which may further result in an implant species having an incorrect depth profile or peak concentration within the processed substrate or workpiece.

Other issues may arise from the liberation of secondary electrons from the collector surface of the Faraday detector. If these electrons are not suppressed, they may not return to the collector and thereby cause underdosing due to the apparent increased beam current reading. Conventional Faraday devices employ various means of suppression to ensure this return. These methods may include, for example, the provision of permanent magnets or electrostatic elements within the body of the measurement device. These suppression methods themselves may also cause dose errors at low ion energy due to unwanted deflection of the incoming ions. This is of particular concern if the Faraday is, for example, used to generate a beam profile that subsequently informs a controller how quickly to scan the ion beam in order to provide uniform dose across the wafer or other workpiece.

The present disclosure appreciates that previous efforts have been made to provide more precise and accurate measurements of ion current and the dosimetry of any workpiece implanted with these ions. However, these efforts have not yet overcome a fundamental constraint in that they have not accurately determined the neutral fraction transported within the ion beam, and as a result, have failed to calibrate the ion current accurately. Accordingly, it has been recognized in the present disclosure that by accurately generating, detecting and measuring secondary electron yield (γ) information attributable to only the energetic neural component of the particle beam, as well as the secondary electron yield information attributable to the combination of the energetic neutral and energetic ion components of the particle beam, an accurate characterization of the extent of neutralization of the particle beam can be achieved.

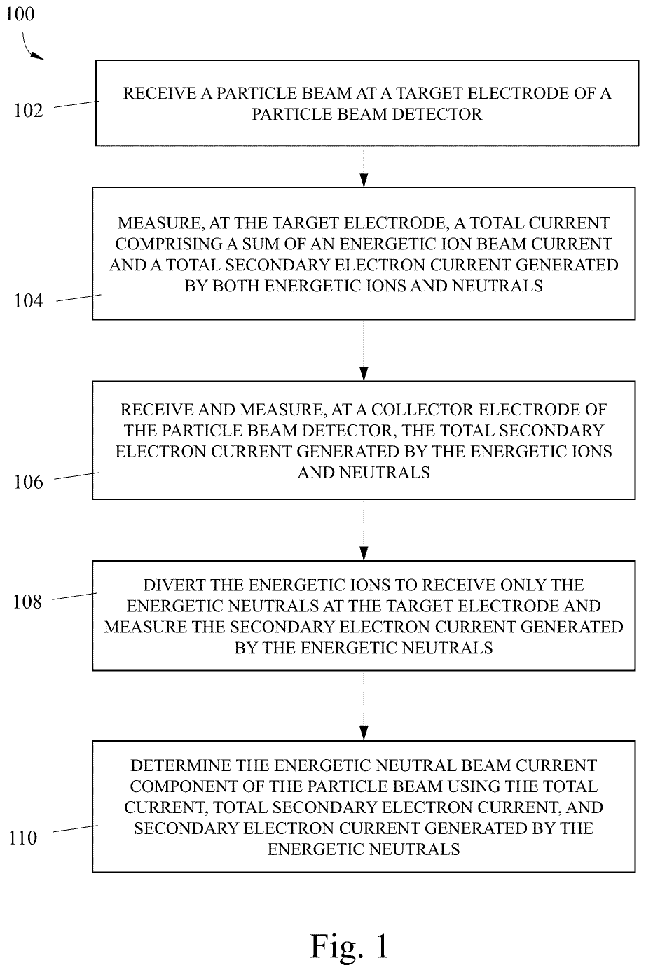

Referring initially to FIG. 1, a flowchart illustrates a method 100 of determining an energetic neutral beam current component of a particle beam having both energetic ions and energetic neutrals, in accordance with an exemplary embodiment. As shown in block 102, the method begins by receiving a particle beam at a target electrode of a particle beam detector. Specific example embodiments of such a particle beam detector are described in further detail hereinafter. If left undisturbed, the particle beam entering the particle beam detector may include both energetic ions and energetic neutrals (such as could be produced through one or more the phenomena as described above). The particle beam generates a total current at the target electrode, which total current represents a sum of the ion beam current and a total secondary electron current resulting from the impact of both the energetic ions and the energetic neutrals on the target electrode. This total current is measured by the particle beam detector, as indicated in block 104.

In addition, a collector electrode is configured within the particle beam detector so as to collect (i.e., receive) and measure the total secondary electron current generated at the target electrode, as indicated in block 106. Then, as indicated in block 108, the energetic ions are selectively diverted from the particle beam (as will be described in further detail) such that only the energetic neutrals are received at the target electrode. The resulting secondary electron current generated by the energetic neutrals is measured. Accordingly, with these measurements, the energetic neutral beam current component of the particle beam may then be determined, as indicated in block 110 from the total current, the total secondary electron current, and the secondary electron current generated by the energetic neutrals. Stated another way, using the above described process and measurements, a ratio (i.e., percentage) of energetic neutral beam current to energetic ion beam current may be determined by determining a ratio of the secondary electron current generated by the energetic neutrals to the secondary electron current generated by the energetic ions. This result can also be expressed in terms of a percentage of ion beam neutralization, corresponding to a ratio of the secondary electron current generated by the energetic neutrals to the total secondary electron current that is generated by both energetic neutrals and ions.

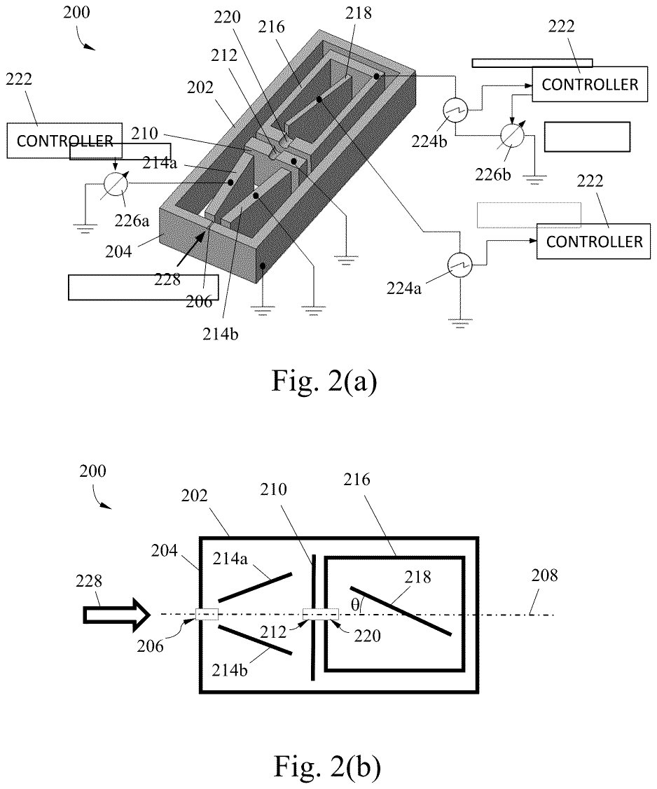

Referring simultaneously now to both FIG. 2(a) and 2(b), there is shown, respectively, a cutaway perspective view and a schematic representation of an exemplary particle beam detector 200 that may be used to implement the method illustrated in FIG. 1, in accordance with an exemplary embodiment. As is illustrated, the particle beam current detector 200 includes an external housing 202 that may be formed from, for example, graphite or other suitable materials. A front surface 204 of the external housing 202 has a first aperture 206 formed therein, the first aperture 206 being disposed along a beam axis 208 (shown in FIG. 2(b)). A strike plate 210 is disposed within the external housing 202 and positioned parallel to the front surface 204, the strike plate 210 having a second aperture 212 that is also disposed along the beam axis 208. One or more deflector electrodes (plates) 214a, 214b are disposed within the external housing 202, located between the front surface 204 and a first side of the strike plate 210. In addition, an internal housing 216 is disposed adjacent a second side of the strike plate 210, and at least partially surrounds a target electrode 218 disposed at an incident angle θ with respect to the beam axis 208. In preferred embodiments, the target 218 will be disposed at values of θ between 15 degrees and 70 degrees relative to the beam axis 208. The incident angle may be selected so as to optimize the yield of secondary electrons while minimizing sputtering of the target electrode material. Angles closer to normal incidence will have a lower secondary electron yield and which will also reduce the sensitivity of gamma to variations in the ion beam angle.

In the embodiment illustrated, the internal housing 216 serves as a collector electrode and includes a third aperture 220 that is also disposed along the beam axis 218. FIG. 2(a) further illustrates a controller 222 configured to receive current measurements from current measurement devices 224a, 224b, respectively coupled to the target electrode 218 and the inner housing (collector electrode) 216. The controller 222 may additionally provide control signals to variable voltage supplies 226a, 226b, in order to provide selectively controllable bias voltages, respectively, to the deflector plates 214a, 214b and the inner housing (collector electrode) 216. Further, when used in conjunction with an ion implantation system, the controller 222 may also include, or be communicatively coupled to, a dosimetry controller (not shown) to calculate a required exposure time of a workpiece based on the required implant dose and beam current information determined by the particle beam current detector 200.

In a first mode of operation, the deflector plates 214a, 214b, are selectively biased so as to permit both energetic ions and energetic neutrals from an input particle beam 228 to pass through each of the apertures 206, 212, 220 and reach the target electrode 218. The apertures may be circular in cross section and of substantially similar diameters. In other embodiments, the apertures may taper at an angle designed to match a divergence angle of the ion beam. In a preferred embodiment, the apertures may be of a slit design, such that the aperture is elongated in a vertical direction, orthogonal to the beam axis. In a second mode of operation, the deflector plates 214a, 214b, are selectively biased so as to deflect the energetic ions from the beam axis 208 such that only the energetic neutrals reach the target electrode 218. By performing one or more measurements where both energetic ions and energetic neutrals reach the target electrode 218, as well as one or more measurements where only the energetic neutrals reach the target electrode 218, a quantification of the neutral particle contribution to the particle beam 228 may be determined.

In still further detail, the input particle beam 228 travels along the beam axis 208 and enters the particle beam current detector 200 through the first aperture 206. At this location, the particle beam 228 is assumed to include a composition of charged ions having a percentage of energetic neutral particles, atoms or molecules included therein. Again, the energetic neutral particles contained withing the particle beam 228 may, for example, be generated as the result of a charge exchange interaction of beam ions with a background gas (e.g., as a result of photoresist outgassing from the interaction of the ion beam with a target substrate).

The deflector plates 214a, 214b can be configured to be energized (for example) to a potential between about 0 volts (V) and about 6000 V. In the exemplary embodiment illustrated in FIG. 2(a), the external housing 202, deflector plate 214b and strike plate 210 are connected to ground. As such, when deflector plate 214a is also coupled to ground potential (via the variable voltage supply 226a), both the energetic ions and the energetic neutrals of the particle beam 228 entering the detector 200 through the first aperture 206 also pass through the second aperture 212 and the third aperture 220, striking the target electrode 218. In this mode of operation (i.e., the deflector plates 214a, 214b do not alter the path of the energetic ions within the particle beam 228), the current measurement device 224a measures a total target electrode current (T₁) that comprises a sum of the energetic ion beam current (I), generated by the positively charged energetic ions acquiring electrons from the material of the target electrode 218, and a first secondary electron current (C₁) that is generated by both the energetic ions and the energetic neutrals striking the target electrode. In addition, a collector bias voltage applied to the internal housing/collector electrode 216 is provided the variable voltage supply 226b (for example, to a potential between 0V and about +10V). This collector bias voltage causes the internal housing/collector electrode 216 to attract the secondary electrons, generated in the target electrode 218 from the energetic neutrals and ions, and prevent them returning to the target electrode 218. Therefore, the first secondary electron current (C₁) can be directly measured with the current measuring device 224b.

In order to isolate and measure the energetic neutral beam contribution to secondary electron current, a bias voltage is applied to deflector plate 214a, which causes the energetic ions within the particle beam to be deflected away from the beam axis 208 and, for example, impact the strike plate 210. In any case, these energetic ions are thus prevented from passing through the second and third apertures 212, 220 and reaching the target electrode 218. The specific voltage applied to deflector plate 214a may be determined by the voltage differential required to deflect an ion beam of a given rigidity, such that ions do not pass through the second and third apertures 212, 220. Thus, when only the energetic neutrals reach the target electrode, the resulting current measured at the target electrode 218 will be a second secondary electron current (T₂) that is generated only by the energetic neutrals. Notably, the second secondary electron current (T₂) may be measured directly with the current measuring device 224a and/or with the current measuring device 224b since the second secondary electron current (T₂) generated by the energetic neutrals at the target electrode 218 is captured by the inner housing/collector electrode 216.

Accordingly, by using the three measured current parameters—i.e., the total target electrode current (T₁) and the first secondary electron current (C₁) measured from both the energetic ion and energetic neutral beam components, and the second secondary electron current (T₂) measured from only the energetic neutral beam component, the energetic neutral beam current component (N) may be derived.

As stated previously, the total target electrode current (T₁) represents the sum of the energetic ion beam current (I) and the first secondary electron current (C₁) that is generated by both the energetic ions and the energetic neutrals striking the target electrode. That is:

T₁=I+C₁ (eq. 1)

The first secondary electron current (C₁) is a secondary electron yield function (γ) of both the energetic ion beam current (I) and the energetic neutral beam current component (N), which may be expressed as:

C₁=γ(I+N) (Eq. 2),

so that:

T₁=I+γ(I+N)=I+γI+γN (Eq. 3)

Correspondingly, the second secondary electron current (C₂) is the secondary electron yield function (γ) of the energetic neutral beam current component (N):

T₂=γN (Eq. 4);

and thus

γ=T₂/N (Eq. 5)

Because (Eq. 1) may be rewritten as I=T₁−C₁, (Eq. 3) may also be rewritten as:

T₁=T₁−C₁+γ(T₁−C₁)+γN (Eq. 6)

Substituting Eq. 4 into Eq. 6 yields:

T₁=T₁−C₁+γ(T₁−C₁)+T₂ (eq. 7)

Rearranging these terms as an expression of the secondary yield function (γ):

γ=(C₁−T₂)/(T₁−C₁) (Eq. 8)

Equating the two expressions of the secondary yield function (γ) in (Eq. 5) and (Eq. 8) gives:

T₂/N=(C₁−T₂)/(T₁−C₁); therefore

N=T₂·(T₁−C₁)/(C₁−T₂) (Eq. 9)

And recalling that the energetic ion beam current, I=T₁−C₁, then (Eq. 9) can also be expressed as N=I·T₂/(C₁−T₂), such that:

N/I=T₂/(C₁−T₂) (Eq. 10)

That is, the ratio of energetic neutral beam current to energetic ion beam current can be determined from the ratio of the secondary electron current generated by the energetic neutrals to the secondary electron current generated by the energetic ions (since the secondary electron current generated by the energetic ions is C₁−T₂). From these equations, the percentage of neutralization of the ions in the particle beam due to collisions with the background gas may also be expressed as N/(N+I)·100%, and therefore in terms of the measured parameters obtained from the particle beam current detector 200, this expression algebraically reduces to (calculations omitted):

% Ion Beam Neutralization=N/(N+I)·100%=T₂/C₁·100% (eq. 11)

In other words, the percentage of ion beam neutralization of the particle beam corresponds to the percentage of secondary electron current generated by the energetic neutrals (i.e., the defined “second” secondary electron current, T₂) with respect to the total secondary electron current generated by both energetic neutrals and ions (i.e., the defined “first” secondary electron current, C₁).

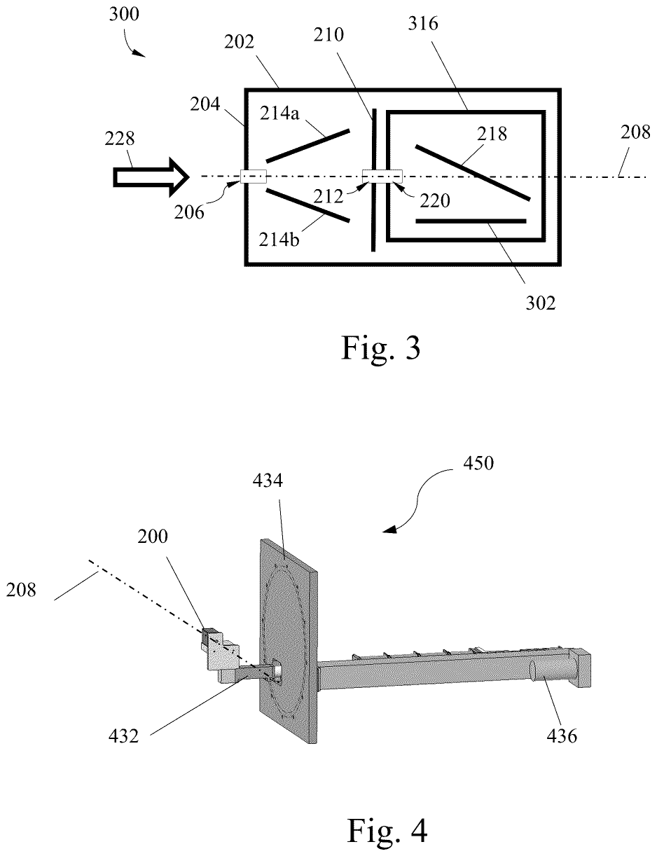

Referring now to FIG. 3, there is shown a schematic representation of a beam current measurement device 300 that is an alternative embodiment of the particle beam detector illustrated in FIG. 2(b). For ease of illustration, like components are designated with like reference numerals among the figures. In this embodiment, the beam current measurement device 300 includes a collector electrode 302 proximate the target electrode 218 that is separate from (and disposed within) the internal housing 316. Here, the internal housing 316 is not used as the collector electrode, but may be formed from a ferromagnetic material (for example, stainless steel) so as to serve as a ferromagnetic shield, and thereby prevent magnetic fields generated by other components (e.g., an electromagnet disposed within the beamline of an ion implanter) from interfering with collection of the secondary electrons generated from the target electrode 218. It will also be appreciated that, in this embodiment, a current measuring device and a variable voltage supply, such as shown in FIG. 2(a), would be connected directly to the collector electrode 302 instead of the external housing 316.

FIG. 4 shows an exemplary embodiment of the beam current measurement device 200 for use within an ion implantation system 450. The ion beam 228 defines a beam axis 208 which is configured to selectably intercept the device 200. The device may, for example, be mounted on an actuation mechanism 432. The mechanism is operably coupled through a vacuum interface plate 434 to a drive motor 436, capable of translating the device into the path of the ion beam. It will be appreciated that the plate 434 is exemplary, and could be in the form of a door or other suitable vacuum interface with a vacuum feedthrough. In other embodiments, the mechanism 432 can selectively rotate the workpiece in order to intercept the ion beam 228. In yet another embodiment, the detector is rigidly coupled to the interface 434 and the ion beam is scanned by electrostatic or magnetic means in order to intercept the particle beam measurement device.

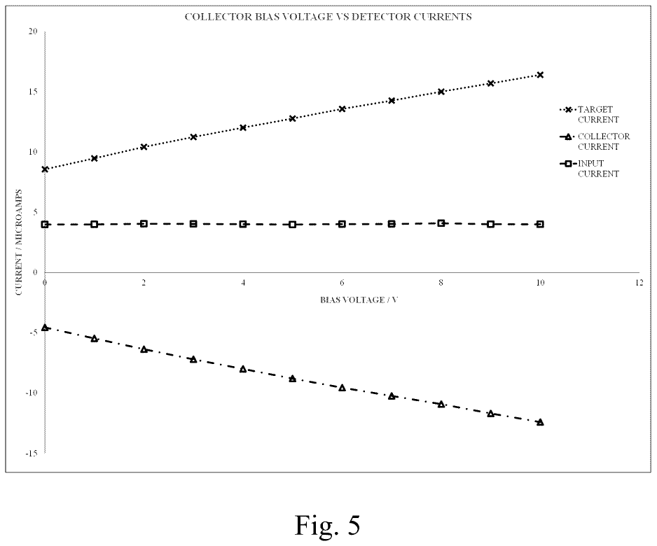

FIG. 5 provides for a mode of operation whereby the operational integrity of the particle beam measurement device may be verified. In this mode of operation, the deflector plates (214a and 214b in FIG. 2(a) and FIG. 2(b)) are both substantially grounded and the ion beam is allowed to intercept the target electrode. Once an ion current is detected, the collector bias voltage is ramped from an initial value of about 0V up to a maximum value of about +10V. This serves as a health check of the detector apparatus prior to use, for example before implanting a workpiece in an ion implanter. In normal operation, as shown in FIG. 5, the collector current will linearly become more negative as the bias voltage increases. Simultaneously, the target current will linearly become more positive as the bias voltage is ramped, with the result that the sum of the currents will be a constant if the device is working properly.

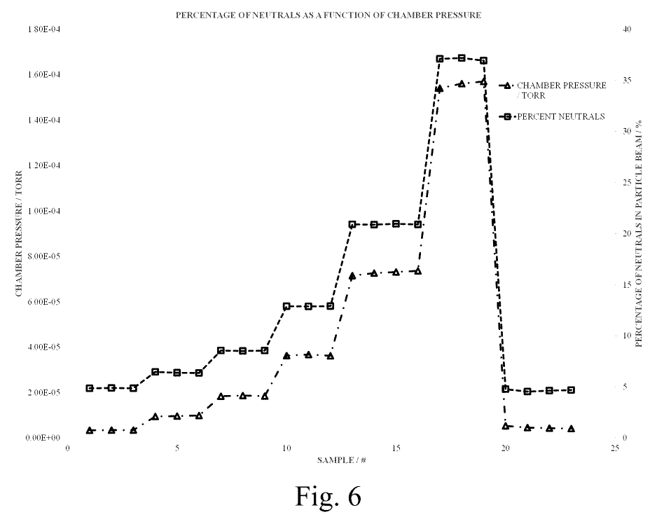

FIG. 6 provides a further exemplary mode of operation of the particle beam measurement device. Here the pressure within the beamline is artificially controlled to provide known number densities of molecules of known charge exchange cross section. The neutral fraction, obtained using the method described in FIG. 1 and using the apparatus of FIG. 2(a), may be plotted against the pressure, yielding a 1:1 correlation as shown in FIG. 6. Further, the neutral fraction returns to baseline values when the pressure is reduced to the initial baseline. Thus by coupling the output from the particle beam current measurement device with a pressure controller, a further calibration check is envisaged for the device.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some embodiments, the terms “approximately”, “about” and “substantially” can indicate a value of a given quantity that varies within 5% of the value (e.g., ±1%, 2%, ±3%, ±4%, ±5% of the value). These values are merely examples and are not intended to be limiting. It is to be understood that the terms “approximately”, “about” and “substantially” can refer to a percentage of the values as interpreted by those skilled in relevant art(s) in light of the teachings herein.

1. A method of determining an energetic neutral beam current component of a particle beam having both energetic ions and energetic neutrals, the method comprising:
receiving the particle beam at a particle beam detector;
determining a first value corresponding to a first secondary electron current generated by both the energetic ions and the energetic neutrals, and determining a second value corresponding to a second secondary electron current generated by the energetic neutrals; and
quantifying the neutral beam current component with respect to an energetic ion beam current of the particle beam using the determined first and second values.

2. The method of claim 1, wherein quantifying the neutral beam component with respect to the energetic ion beam current of the particle beam comprises determining a ratio of the second value to the first value.

3. The method of claim 1, wherein the first value is determined by:
receiving the particle beam at a target electrode of the particle beam detector;
collecting, at a collector electrode, secondary electrons generated at the target generated by both the energetic ions and the energetic neutrals of the particle beam; and
directly measuring, at the collector electrode, the first secondary electron current generated by both the energetic ions and the energetic neutrals.

4. The method of claim 3, further comprising:
determining the second value by separating the energetic ions from the energetic neutrals so as to receive only the energetic neutrals at the target electrode, and directly measuring the second secondary electron current generated by the energetic neutrals.

5. The method of claim 4, wherein separating the energetic ions from the energetic neutrals comprises electrically biasing one or more deflector electrodes of the particle beam detector so as to deflect the energetic ions away from a beam axis toward the target electrode.

6. A method of characterizing a neutralization of a particle beam having both energetic ions and energetic neutrals, the method comprising:
receiving the particle beam at a target electrode of a particle beam detector;
measuring, at the target electrode, a total target electrode current (T₁) that comprises a sum of an energetic ion beam current (I) and a first secondary electron current (C₁), the first secondary electron current (C₁) being generated at the target electrode by both the energetic ions and the energetic neutrals;
receiving and measuring, at a collector electrode of the particle beam detector, the first secondary electron current (C₁) emitted from the target electrode;
selectively diverting the energetic ions of the particle beam such that only the energetic neutrals are received at the target electrode, and measuring a second secondary electron current (T₂), the second secondary electron current (T₂) being generated at the target electrode only by the energetic neutrals; and
determining an energetic neutral beam current component (N) of the particle beam using the total target electrode current (T₁), the first secondary electron current (C₁), and the second secondary electron current (T₂).

7. The method of claim 6, wherein the energetic neutral beam current component (N) of the particle beam is determined by the formula:
N=I·T₂/(C₁−T₂); wherein I=T₁−C₁.

8. The method of claim 6, further comprising determining a percentage of ion beam neutralization of the particle beam using the expression:
% ion beam neutralization=N/(N+I)·100%=T₂/C₁·100%.

9. The method of claim 6, wherein selectively diverting the energetic ions from the energetic neutrals comprises electrically biasing one or more deflector electrodes of the particle beam detector so as to deflect the energetic ions away from a beam axis toward the target electrode.

10. A particle beam detector apparatus, comprising:
a target electrode configured to receive an incident particle beam, the incident particle beam having both energetic ions and energetic neutrals;
a collector electrode configured to capture secondary electrons generated at the target electrode; and
one or more deflection electrodes configured to selectively divert the energetic ions away from a beam axis that intersects the target electrode.

11. The apparatus of claim 10, further comprising:
an external housing having a front surface;
a first aperture formed through the front surface, the first aperture disposed along the beam axis and configured to pass the incident particle beam therethrough;
a strike plate disposed within the external housing positioned parallel to the front surface;
a second aperture formed through the strike plate, the second aperture also being disposed along the beam axis;
one or more deflector electrodes disposed within the external housing and disposed between the front surface and a first side of the strike plate;
an internal housing disposed adjacent a second side of the strike plate, the internal housing at least partially surrounding the target electrode; and
a third aperture formed through the internal housing, the third aperture also being disposed along the beam axis.

12. The apparatus of claim 11, wherein the internal housing comprises the collector electrode.

13. The apparatus of claim 11, wherein the collector electrode is disposed within the internal housing.

14. The apparatus of claim 13, wherein the internal housing is selected from a material so as to serve as a ferromagnetic shield, thereby preventing magnetic fields from interfering with collection of the secondary electrons generated at the target electrode.

15. The apparatus of claim 10, wherein the target electrode is disposed at incident angle with respect to the beam axis, the incident angle selected to result in a desired yield of secondary electrons.

16. The apparatus of claim 11, wherein the first, second and third apertures are disposed so to allow both the energetic ions and the energetic neutrals of the incident particle beam to reach the target electrode when the one or more deflector electrodes are in an unbiased state.

17. The apparatus of claim 16, wherein the second and third apertures are disposed so to allow only the energetic neutrals of the incident particle beam to reach the target electrode when the one or more deflector electrodes are in a biased state.

18. The apparatus of claim 17, wherein the strike plate is configured to prevent energetic ions, selectively diverted from the beam axis when the one or more deflector electrodes are in the biased state, from reaching the target electrode.

19. A particle beam current detection system, comprising:
a particle beam detector, the particle beam detector further comprising:
a target electrode configured to receive an incident particle beam, the incident particle beam having both energetic ions and energetic neutrals;
a collector electrode configured to capture secondary electrons generated at the target electrode; and
one or more deflection electrodes configured to selectively divert the energetic ions away from a beam axis toward the target electrode;
a first current measuring device coupled to the target electrode;
a second current measuring device coupled to the collector electrode;
a first variable voltage supply coupled to the one or more deflection electrodes; and
a second variable voltage supply coupled to the collector electrode.

20. The system of claim 19, wherein the particle beam detector further comprises:
an external housing having a front surface;
a first aperture formed through the front surface, the first aperture disposed along the beam axis and configured to pass the incident particle beam therethrough;
a strike plate disposed within the external housing positioned parallel to the front surface;
a second aperture formed through the strike plate, the second aperture also being disposed along the beam axis;
one or more deflector electrodes disposed within the external housing and disposed between the front surface and a first side of the strike plate;
an internal housing disposed adjacent a second side of the strike plate, the internal housing at least partially surrounding the target electrode; and
a third aperture formed through the internal housing, the third aperture also being disposed along the beam axis.

21. The system of claim 20, wherein the internal housing comprises the collector electrode.

22. The system of claim 20, wherein the collector electrode is disposed within the internal housing, and wherein the internal housing is selected from a material so as to serve as a ferromagnetic shield, thereby preventing magnetic fields from interfering with collection of the secondary electrons generated at the target electrode.

23. The system of claim 20, wherein:
the first current measuring device is configured to measure a total target electrode current (T₁) that comprises a sum of an energetic ion beam current (I) and a first secondary electron current (C₁), the first secondary electron current (C₁) being generated at the target electrode by both the energetic ions and the energetic neutrals; and
the second current measuring device is configured to measure the first secondary electron current (C₁) emitted from the target electrode and collected by the collector electrode.

24. The system of claim 20, wherein:
one or both of the first current measuring device and second current measuring device are configured to measure a second secondary electron current (T₂), the second secondary electron current (T₂) being generated at the target electrode only by the energetic neutrals; and
wherein an energetic neutral beam current component (N) of the particle beam is determined using the total target electrode current (T₁), the first secondary electron current (C₁), and the second secondary electron current (T₂).

25. The system of claim 24, wherein the energetic neutral beam current component (N) of the particle beam is determined by the formula:
N=I*T₂/(C₁−T₂); wherein I=T₁−C₁.

26. The system of claim 24, wherein a percentage of ion beam neutralization of the particle beam is determined using the expression:
% ion beam neutralization=N/(N+I)·100%=T₂/C₁·100%.
